(19) United States
(12) Patent Application Publication
(10) Pub. No.: US 2005/0142793 A1
(43) Pub. Date: Jun. 30, 2005

(54) Method of manufactuing inductor in semiconductor device

(76) Inventor: Kyeong Keun Choi, Soowon-Shi (KR)

Correspondence Address: JACOBSON HOLMAN PLLC, 400 SEVENTH STREET N.W., SUITE 600, WASHINGTON, DC, 20004, US

(21) Appl. No.: 10/878,318

(22) Filed: Jun. 29, 2004

(30) Foreign Application Priority Data
Dec. 30, 2003 (KR) 2003-100174

(51) Int. Cl. H01L 21/20

(52) U.S. Cl. 438/381

(57) ABSTRACT

The present invention related to a method of manufacturing an inductor in a semiconductor device. A wire for an inductor is thickly formed by performing at least two damascene process in the same pattern of different patterns, thus reducing resistance and obtain a good Q (Quality) factor. Therefore, the present invention has effects that it can improve reliability of a process and electrical properties of a device.

### BACKGROUND

1. Field of the Invention

The present invention relates to a method of manufacturing an inductor in a semiconductor device, and more specifically, to a method of manufacturing an inductor in a semiconductor device wherein a wire for an inductor is formed thickly.

2. Discussion of Related Art

In CMOS RF technology, RF is lowered to the level of the base band through direct conversion, etc. so that a RF chip can be fabricated even with a common CMOS process. This is core technology that integrates the base band and RF into a single chip and enables SoC (System On Chip) for wireless communication devices to be developed. For SoC, it is required that an active device and a passive device be formed on a single semiconductor substrate by a batch process, thus fabricating a high frequency integrated circuit. When this high frequency integrated circuit is fabricated, components capable of performing functions such as amplification of a weak signal and frequency conversion are used to significantly reduce the number of components used and also miniaturize the high frequency system, thus increasing the production yield.

FIG. 1 is a 3-D view showing an exemplary RF CMOS having an active device and a passive device formed on the same substrate. As shown in FIG. 1, in the RF CMOS, electrical connection portions to unit elements as well as an active device and a passive device are formed on the semiconductor substrate in batch at the same time. Therefore, the RF CMOS is small is size, high in reliability and uniform in the properties compared to the conventional high frequency circuit substrate. Furthermore, there is no need for additional packaging of individual components. It is known that it is possible to lower the manufacturing cost and increase the market competitiveness of wireless communication devices compared to a case where the high frequency circuit is fabricated using individual components. That is, in order to fabricate the high frequency circuit, a high frequency circuit substrate in which the active device and the passive device being individual components are mounted on a ceramic substrate is used in the prior art. As the wireless system is miniaturized and mass-produced, however, the circuit substrate is replaced with a semiconductor substrate.

As such, the RF CMOS is mainly classified into the active device and the passive device. The passive device includes a resistor, an inductor, a capacitor and a wire between the active device and the passive device. In this case, the properties of the passive device are provided as data by measuring the RF characteristic from a standard device having a defined structure and size, extracting equivalent circuit parameters and inducing characteristic rules. At this time, the inductor is usually fabricated in a spiral structure. The properties of the inductor are changed depending on a line width, a distance, a spiral number, etc. of a metal. Furthermore, these properties are provided as data by extracting equivalent circuit parameters from the RF CMOS device and inducing the characteristic rules.

In case of the inductor being the passive device, it is required that resistance be lowered and parasitic capacitance between the wires be reduced so as to obtain a high Q (quality) factor. The process of manufacturing the inductor uses a damascene process if a wire is formed using Cu in order to implement a desired pattern. The damascene process consists of a combination of various processes such as an oxide film deposition process, an exposure process, an etch process, a chemical mechanical polishing process and a metal deposition process.

In these processes, in order to form a thick wire for an inductor when an inductor wire is formed, the wire is formed by means of the etch process after the inductor pattern is formed. At this time, there is a limit to forming a deep inductor pattern because of an etch selective ratio between a photoresist pattern and an oxide film.

### SUMMARY OF THE INVENTION

The present invention is directed to a method of manufacturing an inductor in a semiconductor device wherein a wire for an inductor is formed thickly by performing at least two damascene process in the same pattern or different patterns, thus reducing resistance, obtaining a good Q (Quality) factor, and improving reliability of the process and the electrical properties of the device.

According to a preferred embodiment of the present invention, there is provided a method of manufacturing an inductor in a semiconductor device, comprising: a first step of forming an interlayer insulating film on a semiconductor substrate, a second step of forming a damascene pattern in the interlayer insulating film, and a third step of forming a metal wire within the damascene pattern, wherein the first to third steps are repeatedly performed to form wires that are vertically connected with no change in a width and have an increased thickness.

In the above, it is preferred that the metal wire is formed using copper.

The step of forming the metal wire comprises the steps of forming a barrier metal layer on the whole structure including the damascene pattern, forming a metal seed layer on the whole structure including the damascene pattern, and forming a metal wire within the damascene pattern by means of an electroplating method.

The step of forming the metal wire can comprise the steps of forming a barrier metal layer on the whole structure including the damascene pattern, forming a metal seed layer on the whole structure including the damascene pattern, stripping the metal seed layer on the interlayer insulating film, thus leaving the metal seed layer remained only within the damascene pattern, and forming a metal wire within the damascene pattern by means of an electroplating method.

The step of forming the metal wire can comprise the steps of forming a barrier metal layer on the whole structure including the damascene pattern, forming a metal seed layer on the whole structure including the damascene pattern, stripping the metal seed layer and the barrier metal layer on the interlayer insulating film, thus leaving the barrier metal layer and the metal seed layer remained only within the damascene pattern, and forming a metal wire within the damascene pattern by means of an electroplating method.

The barrier metal layer can be formed by means of a single atomic deposition method.

After the barrier metal layer is formed, the step of stripping the barrier metal layer at the bottom of the damascene pattern can be further included. The barrier metal layer at the bottom of the damascene pattern can be stripped in a PVD reactor in a RF etch mode, or in a RIE reactor or MERIE reactor anistropically.

After the metal wire is formed, the step of performing an annealing process can be further comprised. The annealing process can be performed in a furnace and is performed in a N₂/H₂ atmosphere at a temperature of 100° C. to 200° C. for 30 minutes to 3 hours.

### BRIEF DESCRIPTION OF THE DRAWINGS

FIG. 1 is a 3-D view showing an exemplary RF CMOS having an active device and a passive device formed on the same substrate; and

FIG. 2A to FIG. 2F are cross-sectional views shown to explain a method of manufacturing an inductor in a semiconductor device according to an embodiment of the present invention.

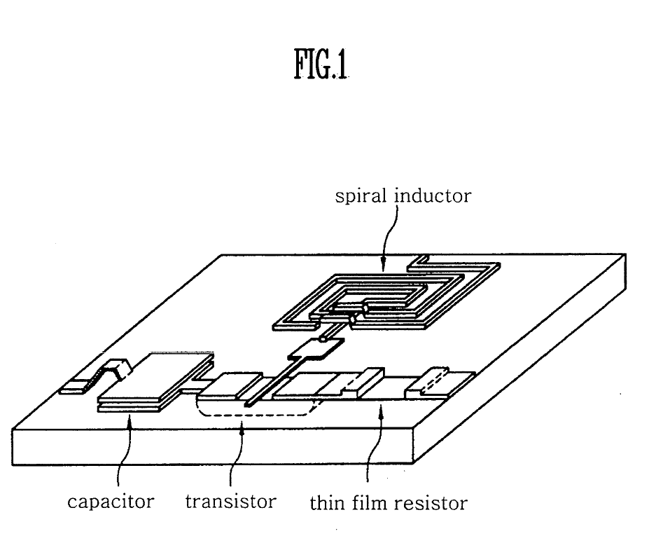

### DETAILED DESCRIPTION OF PREFERRED EMBODIMENTS

Now the preferred embodiments according to the present invention will be described with reference to the accompanying drawings. Since preferred embodiments are provided for the purpose that the ordinary skilled in the art are able to understand the present invention, they may be modified in various manners and the scope of the present invention is not limited by the preferred embodiments described later.

Meanwhile, in case where it is described that one film is “on” the other film or a semiconductor substrate, the one film may directly contact the other film or the semiconductor substrate. Or, a third film may be intervened between the one film and the other film or the semiconductor substrate. Further, in the drawing, the thickness and size of each layer are exaggerated for convenience of explanation and clarity. Like reference numerals are used to identify the same or similar parts.

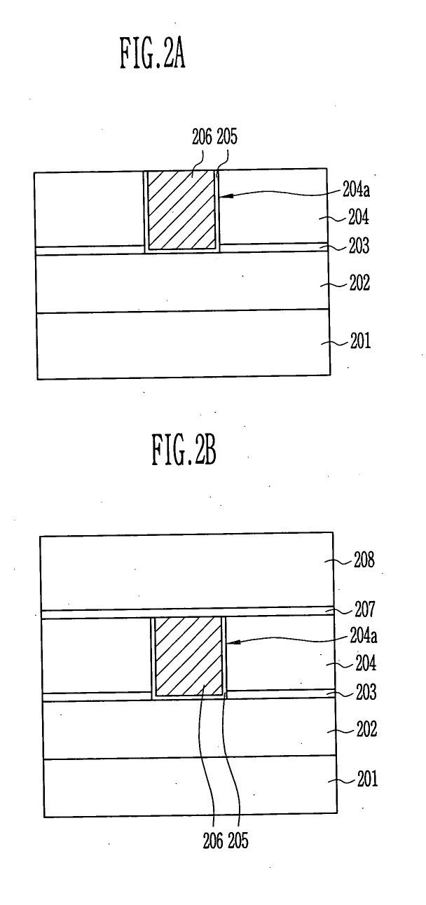

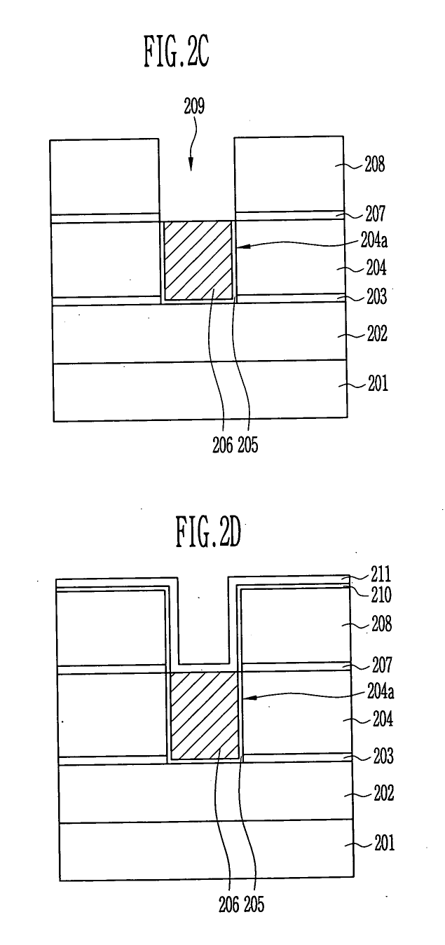

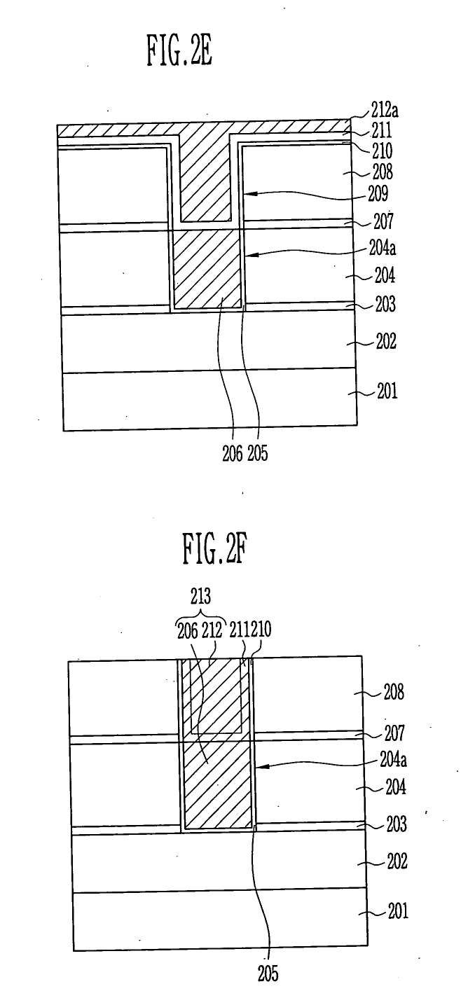

FIG. 2A to FIG. 2F are cross-sectional views shown to explain a method of manufacturing an inductor in a semiconductor device according to an embodiment of the present invention.

Referring to FIG. 2A, a first interlayer insulating film 202 is formed on a semiconductor substrate 201 in which various components (not shown) for forming a semiconductor device are formed.

Though not shown in the drawing, a via hole is formed in a given region of the first interlayer insulating film 202, and a via plug connected to a junction region or an underlying metal wire of the semiconductor substrate 201 is formed in the via hole.

Thereafter, a first insulating barrier layer 203 and a second interlayer insulating film 204 are sequentially formed on the first interlayer insulating film 202. In the above, the first insulating barrier layer 203 can be formed using a SiN film.

A first damascene pattern 204a such as a via hole or a trench is then formed in the second interlayer insulating film 204 by means of a damascene process. A first metal wire 206 is formed within the first damascene pattern 204a. The first metal wire 206 is connected to the junction region or the underlying metal wire (not shown) of the semiconductor substrate 101 through the via plug (not shown) formed in the first interlayer insulating film 202. At this time, it is preferred that the first metal wire 206 is formed using copper.

Meanwhile, it is preferred that a first barrier metal layer 205 is formed at the sidewall and bottom of the first damascene pattern 204a before the first metal wire 206 is formed so as to prevent the metal components of the first metal wire 206 from diffusing into the second interlayer insulating film 204. Thus, the first barrier metal layer 205 formed between the first metal wire 206 and the second interlayer insulating film 204 can prevent the metal components of the first metal wire 206 from diffusing into the second interlayer insulating film 204.

By reference to FIG. 2B, a second insulating barrier layer 207 and a third interlayer insulating film 208 are sequentially formed on the whole structure including the first metal wire 206.

In the above, the second insulating barrier layer 207 can be formed using a SiN film. In more concrete, the second insulating barrier layer 207 can be formed 100 Å to 2000 Å in thickness by supplying SiH₄, N₂, and NH₃ at a temperature of 200° C. to 400° C. In this case, the supply flow of SiH₄ is set to 50 sccm to 500 sccm, the supply flow of N₂ is set to 100 sccm to 10000 sccm and the supply flow of NH₃ is set to 5 sccm to 1000 sccm.

Meanwhile, it is preferred that the third interlayer insulating film 208 is formed using an insulating material having a low dielectric constant such as FSG. It is also preferable that the thickness of the third interlayer insulating film 208 is decided considering a thickness and width of a second metal wire 212 to be formed in a subsequent process. The third interlayer insulating film 208 can be formed 25000 Å to 40000 Å in thickness.

Referring to FIG. 2C, a second damascene pattern 209 such as a via hole or a trench is formed by means of the damascene process. The second damascene pattern 209 can be formed in the same pattern as the first damascene pattern 204a, or can have a wide width or a narrow width, if necessary.

Thereafter, the second insulating barrier layer 207 exposed through the second damascene pattern 209 is etched. It is preferred that the second insulating barrier layer 207 is stripped by reducing its resistance since the second insulating barrier layer 207 has resistance relatively higher than the first metal wire 206. While the second insulating barrier layer 207 is etched, the underlying first metal wire 206 is exposed.

Referring to FIG. 2D, a second barrier metal layer 210 is formed on the whole structure including the second damascene pattern 209. The second barrier metal layer 210 can be formed using Ta or TaN. Thereafter, in order to prevent an increase in contact resistance between a metal wire to be formed in the second damascene pattern 209 and the first metal wire 206, it is preferred that the second barrier metal layer 210 at the bottom of the second damascene pattern 209 is stripped. In this case, the second barrier metal layer 210 can be stripped in a PVD reactor in a RF etch mode, or in a reactive ion etch (RIE) reactor or a magnetically enhanced reactive ion etch (MERIE) reactor in an anisotropic manner. Meanwhile, if the second barrier metal layer 210 is formed by means of a single atomic deposition method, it is formed thinly and is low in resistance. Thus, the process of etching the second barrier metal layer 210 at the bottom of the second damascene pattern 209 can be omitted.

Next, a metal seed layer 211 is formed on the second barrier metal layer 210. It is preferred that the metal seed layer 211 is formed using copper. The metal seed layer 211 can be formed 1000 Å to 2000 Å in thickness.

By reference to FIG. 2E, an electroplating layer 212a is formed on the metal seed layer 211 by means of an electroplating method so that the second damascene pattern 209 is fully buried. An annealing process is then performed. The annealing process can be formed in a furnace in a N₂/H₂ atmosphere under a temperature condition of 100° C. to 200° C. for 30 minutes to 3 hours.

Meanwhile, though not shown in the drawings, before the electroplating method is performed, only the metal seed layer on the third interlayer insulating film 208 can be selectively stripped to leave the metal seed layer 211 remained within only the damascene pattern 209, whereby the electroplating layer 212a is formed only within the damascene pattern 209. In this case, there is an advantage that a load of a chemical mechanical polishing process performed in a subsequent process can be reduced.

Further, before the electroplating method is performed, the barrier metal layer and the metal seed layer on the third interlayer insulating film 208 are selectively stripped to leave the metal seed layer 211 and the barrier metal layer 210 remained only within the damascene pattern 209, and the electroplating layer 212a is then formed by means of an electroless plating method, whereby the electroplating layer 212a is formed only within the damascene pattern 209. Even in this case, there is an advantage that a load of a chemical mechanical polishing process performed in a subsequent process can be reduced.

Referring to FIG. 2F, the electroplating layer (212a in FIG. 2E) on the third interlayer insulating film 208, the second barrier metal layer 210 and other conductive materials are stripped by means of a chemical mechanical polishing process. Meanwhile, the first metal wire 206 formed in FIG. 2A can be formed by the same method as the method of forming the second metal wire 212. Thereby, a wire 213 for the inductor having the first metal wire 206 and the second metal wire 212 is formed.

The second metal wire 212 is directly brought into contact with the first metal wire 206. Further, since the second damascene pattern 209 and the first damascene pattern 204a are formed in the same pattern, the second metal wire 212 can be formed in the same pattern as the first metal wire 206. As a result, a single inductor wire 213 consisting of the first metal wire 206 and the second metal wire 212 is thus formed by means of twice-damascene process. Through the twice-damascene process, it is possible to form the inductor wire 213 that is thicker 3 μm than conventional 6 μm even in a high aspect ratio.

Furthermore, though not shown in the drawing, if the method shown in FIG. 2B to FIG. 2F is repeatedly performed, a more thick inductor wire can be formed even at a high aspect ratio.

According to the present invention as described above, a wire for an inductor is thickly formed by performing at least two damascene process in the same pattern or different patterns, so that resistance is reduced and a good Q (Quality) factor is obtained. Therefore, the present invention has effects that it can improve reliability of a process and electrical properties of a device.

1. A method of manufacturing an inductor in a semiconductor device, comprising:
a first step of forming an interlayer insulating film on a semiconductor substrate;
a second step of forming a damascene pattern in the interlayer insulating film; and
a third step of forming a metal wire within the damascene pattern,
wherein the first to third steps are repeatedly performed to form wires that are vertically connected with no change in a width and have an increased thickness.

2. The method as claimed in claim 1, wherein the metal wire is formed using copper.

3. The method as claimed in claim 1, wherein the step of forming the metal wire comprises the steps of:
forming a barrier metal layer on the whole structure including the damascene pattern;
forming a metal seed layer on the whole structure including the damascene pattern; and
forming a metal wire within the damascene pattern by means of an electroplating method.

4. The method as claimed in claim 1, wherein the step of forming the metal wire comprises the steps of:
forming a barrier metal layer on the whole structure including the damascene pattern;
forming a metal seed layer on the whole structure including the damascene pattern;
stripping the metal seed layer on the interlayer insulating film, thus leaving the metal seed layer remained only within the damascene pattern; and
forming a metal wire within the damascene pattern by means of an electroplating method.

5. The method as claimed in claim 1, wherein the step of forming the metal wire comprises the steps of:
forming a barrier metal layer on the whole structure including the damascene pattern;
forming a metal seed layer on the whole structure including the damascene pattern;
stripping the metal seed layer and the barrier metal layer on the interlayer insulating film, thus leaving the barrier metal layer and the metal seed layer remained only within the damascene pattern; and
forming a metal wire within the damascene pattern by means of an electroplating method.

6. The method as claimed in claim 5, wherein the barrier metal layer is formed by means of atomic layer deposition.

7. The method as claimed in claim 5, further comprising the step of after the barrier metal layer is formed, stripping the barrier metal layer at the bottom of the damascene pattern.

8. The method as claimed in claim 7, wherein the barrier metal layer at the bottom of the damascene pattern is stripped in a PVD reactor in a RF etch mode, or in a RIE reactor or MERIE reactor by an anistropic etch process.

9. The method as claimed in claim 5, further comprising the step of after the metal wire is formed, performing an annealing process.

10. The method as claimed in claim 9, wherein the annealing process is performed in a furnace and is performed in a N₂/H₂ atmosphere at a temperature of 100° C. to 200° C. for 30 minutes to 3 hours.
